(19) United States
(12) Patent Application Publication
(10) Pub. No.: US 2014/0111962 A1
(43) Pub. Date: Apr. 24, 2014

(54) TOUCH SCREEN PANEL

(71) Applicant: DONGWOO FINE-CHEM CO., LTD., Jeollabuk-do (KR)

(72) Inventors: Dae Chul PARK, Seoul (KR); Seung Kook KIM, Seoul (KR); Jong Min KIM, Jeollabuk-do (KR)

(73) Assignee: DONGWOO FINE-CHEM CO., LTD., Jeollabuk-do (KR)

(21) Appl. No.: 14/060,616

(22) Filed: Oct. 23, 2013

(30) Foreign Application Priority Data
Oct. 23, 2012 (KR) 10-2012-0117681

(51) Int. Cl. H05K 9/00

(52) U.S. Cl. CPC H05K 9/00
USPC 361/818

(57) ABSTRACT

A touch screen panel is provided with electromagnetic wave shielding properties. The touch screen panel includes an electromagnetic wave shielding layer on a window substrate. The electromagnetic wave shielding layer may include at least one alloy selected from the group consisting of copper, iron, nickel, aluminum, tin, indium, zinc, gold and silver, and oxides thereof, as an electromagnetic wave shielding material. The electromagnetic wave shielding layer may include at least one electromagnetic wave shielding material selected from the group consisting of polypyrrole, polythiophene, and polyaniline. When the touch screen panel further includes an index matching layer, the electromagnetic wave shielding layer may be formed on at least one face of the index matching layer. When electromagnetic wave shielding material is included in the index matching layer, the index matching layer functions as the electromagnetic wave shielding layer.

### CROSS REFERENCE TO RELATED APPLICATION

This application claims priority to Korean Patent Application No. 10-2012-0117681, filed on Oct. 23, 2012, in the Korean Intellectual Property Office, the entire disclosure of which is incorporated herein by reference.

### BACKGROUND OF THE INVENTION

1. Field of the Invention

The present invention relates to a touch screen panel.

2. Description of the Related Art

A touch screen is a screen equipped with a special input device to receive positional input(s) by touching the screen with a finger or a stylus pen.

The touch screen does not use a keyboard, but instead has a configuration of multi-layer laminates wherein, when the finger of a human or an object, such as a stylus pen, touches a specific character or position displayed on a screen, the touch screen identifies the position and directly receives data through the screen picture, in order to practically treat the data by software stored therein.

A conventional touch screen has been manufactured by first preparing an indium-tin oxide (ITO) film and a window substrate, via their respective processes, followed by the combination of the two. However, in recent years, the window substrate has been integrated with the ITO film through a series of processes.

Touch screen panels having a window substrate and different layers, such as an electrode pattern layer laminated on the window substrate, or the like, are typically driven by DC or AC voltages applied to an electrode pattern or liquid crystal cell. During such processes, electromagnetic waves are emitted.

Problems associated with electromagnetic interference may include, for example, (1) health impairments, (2) electromagnetic wave malfunction, and (3) substrate penetration, or the like. Regarding health impairments, high frequency waves are easily absorbed into the human body and may generate resonance depending upon the amplitude of the frequency or the tissue-type within the human body, hence, causing hot-spot effects. Therefore, a mobile phone may negatively affect the head of a user. On the other hand, low frequency waves have high penetration in terms of the human body and, in particular, the carcinogenic effects of magnetic fields are troublesome.

Electromagnetic wave malfunction causes problems associated with other instruments malfunctioning due to the electromagnetic waves emitted from alternate electronic devices. The prohibition of using a mobile phone inside a hospital or an airplane is now commonplace because the above described interference increases the probability of not only a relatively minor accident, but also the potential for a serious accident that may be life threatening.

With reference to substrate penetration problems, since the electromagnetic waves emitted from a computer or an internal (in-house) local area network (LAN) can be intercepted with an antenna gathering information from the same, problems caused by the above conditions are often pointed out.

### SUMMARY

Accordingly, an object of the present invention is to provide a touch screen panel having an electromagnetic wave shielding capability.

The touch screen panel of the present invention may have an electromagnetic wave shielding layer to prevent the malfunction of peripheral equipment caused by the emission of electromagnetic waves, as well as prevent harmful influences on the human body.

The electromagnetic wave shielding layer may include at least one alloy selected from the group consisting of copper, iron, nickel, aluminum, tin, indium, zinc, gold and silver, and oxides thereof, as an electromagnetic wave shielding material.

The electromagnetic wave shielding layer may include at least one electromagnetic wave shielding material selected from the group consisting of polypyrrole, polythiophene, and polyaniline.

The touch screen panel may further include an index matching layer, and the electromagnetic wave shielding layer may be formed on at least one face of the index matching layer.

The index matching layer may include niobium oxide or silicon oxide, or a mixture thereof.

The electromagnetic wave shielding layer may be formed directly on at least one face of a window substrate.

The touch screen panel may further include an insulating layer, and the electromagnetic wave shielding layer may be formed on at least one face of the insulating layer.

The electromagnetic wave shielding layer may be formed from a composition comprising an electromagnetic wave shielding material, binder resin and solvent.

The electromagnetic wave shielding layer may be an index matching layer.

The index matching layer may include an electromagnetic wave shielding material.

The index matching layer may be prepared by combining niobium oxide or silicon oxide with electromagnetic wave shielding material.

### BRIEF DESCRIPTION OF THE DRAWINGS

The above and other objects, features, and other advantages of the present invention will be more clearly understood from the following detailed description taken in conjunction with the accompanying drawing, in which:

FIG. 1 is a schematic perspective view of a mobile phone as one example to which a touch screen panel of the present invention is applied.

### DETAILED DESCRIPTION

The present invention discloses a touch screen panel with electromagnetic wave shielding properties, which includes an electromagnetic wave shielding layer.

It will be understood that when an element such as a layer, film, region, or substrate is referred to as being “on” another element, it can be directly on the other element or intervening elements may also be present.

Hereinafter, the present invention will be described in detail with reference to the drawing.

The electromagnetic wave shielding layer, according to the present invention, is a layer within a touch screen panel laminate structure provided in the touch screen panel.

Conventionally, a touch screen panel is formed by laminating a non-conductive shielding pattern, an index matching layer, an electrode pattern layer, an insulating layer, and the like, in sequential order, on one face of a window substrate and configured as the outermost part of the panel. Electromagnetic waves are emitted from an electrode and/or circuit board among the configurable elements of the touch screen panel. Accordingly, the electromagnetic wave shielding layer may be placed between an electromagnetic wave emission part and a user.

According to one embodiment of the present invention, an electromagnetic wave shielding layer may be provided on at least one face of a window substrate. In the case where the electromagnetic wave shielding layer is formed on the face of the window substrate at the user side, the electromagnetic wave shielding layer may be connected to a ground electrode by providing a wire on an external frame of an electronic device to fix the window substrate. In the case where the electromagnetic wave shielding layer is formed on the inner panel side of the window substrate, after forming holes in a non-conductive shielding pattern, and filling the holes with a conductive material to apply an electric current to the electromagnetic wave shielding layer, the conductive material may be connected to the ground electrode.

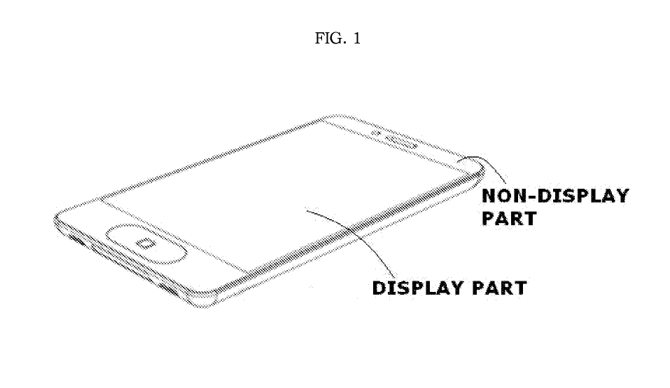

According to another preferred embodiment of the present invention, an electromagnetic wave shielding layer may be provided on at least one face of an index matching layer. However, as shown in FIG. 1, the window substrate may be separated into a display part and a non-display part. In the non-display part, a non-conductive shielding pattern used to hide an inner electrode pattern or circuit board is first formed thereon, and then, an index matching layer is formed on the non-conductive shielding pattern. In this case, the electromagnetic wave shielding layer may be connected to a ground electrode by connecting a wire to a lateral side of the electromagnetic wave shielding layer.

According to another embodiment of the present invention, an electromagnetic wave shielding layer may be provided on at least one face of an insulating layer in a touch screen panel laminate.

According to the above embodiments of the present invention, the electromagnetic wave shielding layer, formed as a layer within the structure of the touch screen panel laminate, may be provided by application of a composition for forming an electromagnetic wave shielding layer. The composition for forming an electromagnetic wave shielding layer may be prepared by including an electromagnetic wave shielding material, binder resin and solvent.

The electromagnetic wave shielding material may be, without limitation, any conventional electromagnetic wave material used in the related art. For instance, the electromagnetic wave shielding material prepared herein may include at least one electromagnetic wave shielding material, for example: metallic materials and oxides thereof, such as an alloy including at least one selected from a group consisting of copper, iron, nickel, aluminum, tin, indium, zinc, gold, and silver, etc.; and conductive polymer materials such as polypyrrole, polythiophene, and polyaniline, etc.

The binder resin may include a polymer resin that forms a film, endows adhesion to an adjacent layer, and has moisture resistance, heat resistance, chemical resistance, and the like. For instance, acrylate resins, urethane resins, epoxy resins, alkyd resins, or the like, may be used alone or in combination with two or more thereof.

The solvent may dissolve or disperse components in the composition and endows workability. The solvents available herein may be, without limitation, water, alcohol, or the like.

Optionally, the composition for forming an electromagnetic wave shielding layer may further include various additives according to the demands thereof. For example, a thickener, an antioxidant, a surfactant, or the like, may be further included without limitation.

Application of the composition for forming an electromagnetic wave shielding layer may be executed by any conventional method known in the related art, without limitation. For example, screen printing, offset printing, spin coating, inkjet printing, or the like, may be used without limitation.

According to another embodiment of the present invention, an index matching layer may also function as an electromagnetic wave shielding layer. In this case, an index matching layer may be prepared by including the electromagnetic wave shielding material described above.

The index matching layer is generally formed by including niobium oxide, silicon oxide, or mixtures thereof. Therefore, according to another embodiment of the present invention, the index matching layer may be prepared by combining niobium oxide or silicon oxide with the electromagnetic wave shielding material described above.

According to the above embodiments of the present invention, the electromagnetic wave shielding layer includes an electromagnetic wave shielding material of a conductive material. The index matching layer adjacent to the electromagnetic wave shielding layer, or used as the electromagnetic wave shielding layer, may be insulated from an electrode pattern layer formed on the index matching layer. The electromagnetic wave shielding layer, according to an embodiment of the present invention is formed to prevent deterioration of insulating properties of the index matching layer and the electrode pattern layer.

The electromagnetic wave shielding layer of the present invention, formed in such a way as described above, may be applied to a touch screen panel and exhibit the desired electromagnetic wave shielding effects.

The touch screen panel, according to the present invention, may be formed as an alternative layer in a touch screen panel laminate structure, as described in the embodiments of the present invention. Otherwise, as described other embodiments of the present invention, the touch screen panel of the present invention may be laminated as an index matching layer containing an electromagnetic wave shielding material. As such, after forming the electromagnetic wave shielding layer, the touch screen panel of the present invention may be prepared according to any preparation method generally used in the related art.

A window substrate used in the present invention may be prepared of any material, without limitation, so long as it has high durability to sufficiently protect the touch screen panel from external forces, and allows a user to optimally view the display, and any window substrate used in the art may be adopted without limitation. For example, glass, polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), or the like, may be used. Glass is used and, more particularly, reinforced glass is used.

A non-conductive shielding pattern is formed on the non-display part of the window substrate according to the present invention.

The non-conductive shielding pattern may be formed using a composition for forming a non-conductive shielding pattern, which includes a shielding agent, binder resin, polymerizable compound, polymerization initiator, solvent, and the like.

The shielding agent used herein may be any shielding agent used in the related art without limitation. For example, a coloring agent, carbon black, aniline black, chromium oxide, iron oxide, titanium black, or mixtures thereof, may be used.

The coloring agent is without limitation, so long as it can express the colors required by the user, and may include, for example, red, green, or blue dyes or pigments; yellow, orange, violet, or brown dyes or pigments, or a combination of the colors; black pigments, carbon black, and the like, which can be used alone or in combination with two or more thereof.

The coloring agent may further include metal powder, white pigments, fluorescent pigments, etc., as necessary.

The pigment may be an inorganic pigment or an organic pigment.

Inorganic pigments are without limitation and may include, for example, barium sulfate, lead sulfate, titanium oxide, yellow lead, Bengal lead, calcium carbonate, chromium oxide, carbon black, or the like.

Organic pigments are without limitation and may include pigments listed by Color Index (C.I.) numbers below.

Yellow pigments may include, for example, C.I. pigment yellow 1, 2, 3, 4, 5, 6, 12, 13, 14, 16, 17, 24, 55, 65, 73, 74, 81, 83, 87, 93, 94, 95, 97, 100, 101, 105, 108, 109, 110, 116, 120, 127, 128, 129, 133, 138, 139, 147, 148, 150, 151, 153, 154, 155, 166, 168, 169, 170, 172, 173, 174, 175, 176, 180, 185, 193, 194, 202, or the like.

Orange pigments may include, for example, C.I. pigment orange 1, 2, 5, 13, 16, 17, 19, 22, 24, 34, 36, 38, 39, 43, 46, 48, 61, 62, 64, 65, 67, 69, 73, 77, or the like.

Red pigments may include, for example, C.I. pigment red 1, 2, 3, 4, 5, 6, 8, 9, 12, 14, 15, 17, 22, 23, 31, 37, 38, 41, 48:1, 48:2, 48:3, 49, 50:1, 52:1, 53, 57:1, 58:4, 60, 63, 64, 68, 81, 88, 90:1, 112, 114, 122, 123, 144, 146, 147, 149, 150, 151, 166, 168, 170, 175, 176, 177, 178, 179, 181, 185, 187, 188, 190, 193, 194, 202, 207, 208, 209, 214, 216, 220, 221, 224, 242, 243, 245, 247, 254, 255, 264, 272, or the like.

Violet pigments may include, for example, C.I. pigment violet 1, 2, 3, 5, 19, 23, 29, 31, 32, 37, 39, 50, or the like.

Blue pigments may include, for example, C.I. pigment blue 1, 15:1, 15:2, 15:3, 15:4, 15:6, 16, 17, 25, 56, 60, 66, 75, 79, or the like.

Green pigments may include, for example, C.I. pigment green 2, 7, 8, 13, 36, 54, or the like.

Brown pigments may include, for example, C.I. pigment brown 1, 22, 23, 25, 27, or the like.

Black pigments may include, for example, C.I. pigment black 1, 7, 31, 32, or the like.

The kinds of dyes are without limitation and may include, for example, azo dyes, anthraquinone dyes, phthalocyanine dyes, quinonimine dyes, quinoline dyes, nitro dyes, carbonyl dyes, methyne dyes, or the like.

The azo dyes are without limitation and may include, for example, C.I. acid yellow 11, C.I. acid orange 7, C.I. acid red 37, C.I. acid red 180, C.I. acid blue 29, C.I. direct red 28, C.I. direct red 83, C.I. direct yellow 12, C.I. direct orange 26, C.I. direct green 28, C.I. direct green 59, C.I. reactive yellow 2, C.I. reactive red 17, C.I. reactive red 120, C.I. reactive black 5, C.I. disperse orange 5, C.I. disperse red 58, C.I. disperse blue 165, C.I. basic blue 41, C.I. basic red 18, C.I. mordant red 7, C.I. mordant yellow 5, C.I. mordant black 7, or the like.

The anthraquinone dyes are without limitation and may include, for example, C.I. bat blue 4, C.I. acid blue 40, C.I. acid green 25, C.I. creative blue 19, C.I. creative blue 49, C.I. disperse red 60, C.I. disperse blue 56, C.I. disperse blue 60, or the like.

The phthalocyanine dyes are without limitation and may include, for example, C.I. pad blue 5, or the like.

The quinonimine dyes are without limitation and may include, for example, C.I. basic blue 3, C.I. basic blue 9, or the like.

The quinoline dyes are without limitation and may include, for example, C.I. solvent yellow 33, C.I. acid yellow 3, C.I. disperse yellow 64, or the like.

The nitro dyes are without limitation and may include, for example, C.I. acid yellow 1, C.I. acid orange 3, C.I. disperse yellow 42, or the like.

Particular non-limited examples of the above dyes, pigments, and carbon black may include Mitsubishi carbon black M1000, Mitsubishi carbon black MA-100, Mitsubishi carbon black #40, Vitoria pure blue (42595), oramine 0 (41000), catilon brilliant flavine (basic 13), rhodamine 6GCP (45160), rhodamine B (45170), sakuranin OK 70:100 (50240), erioglaucine X (42080), NO. 120/Lionel yellow (21090), Lionel yellow GRO (21090), symuler fast yellow GRO (21090), symuler fast yellow 8GF (21105), benzidine yellow 4J-564D (21095), paliotol yellow L0960 (pigment yellow 139), yellow pigment E4-GN (pigment yellow 150 derivative), symuler fast red 4015 (12355), Lionel red 7B4401 (15850), fastogen blue JGR-L (74160), Lionel blue SM (26150), Lionel blue ES (pigment blue 15:6, pigment blue 1536), lionogen red GD (pigment red 168, pigment red 108), chromophthal red A2B (pigment red 177), ilgapore red B-CF (pigment red 254), heliogen green L8730 (pigment green 7), Lionel green 2YS (pigment green 36), or the like.

The binder resin plays a role in supporting the pattern and may be a copolymer of a monomer having a carboxyl group, and another monomer having an unsaturated bond.

The monomer having a carboxyl group is an unsaturated carboxylic acid having at least one carboxyl group in the molecule and may include, for example, monocarboxylic acids such as acrylic acid, methacrylic acid, crotonic acid, etc.; dicarboxylic acids such as fumaric acid, metaconic acid, itaconic acid, etc.; and the anhydrides thereof, and the like.

The monomers having an unsaturated bond are without limitation so long as they are any monomer having an unsaturated double bond copolymerizable with the monomer having the carboxyl group. Particular examples thereof may include unsaturated carboxylic acid ester compounds, such as methyl(meth)acrylate, ethyl(meth)acrylate, butyl(meth)acrylate, 2-hydroxyethyl(meth)acrylate, etc.; unsubstituted or substituted alkylester compounds of unsaturated carboxylic acids, such as aminoethyl(meth)acrylate; unsaturated carboxylic acid ester compounds having alicyclic substituents, such as cyclopentyl(meth)acrylate, cyclohexyl(meth)acrylate, methylcyclohexyl(meth)acrylate, cycloheptyl(meth)acrylate, cyclooctyl(meth)acrylate, cyclopentenyl(meth)acrylate, cyclohexenyl(meth)acrylate, cycloheptenyl(meth)acrylate, cyclooctenyl(meth)acrylate, isobornyl(meth)acrylate, adamantyl(meth)acrylate, norbornyl(meth)acrylate, etc.; unsaturated carboxylic acid ester compounds having thermo-curable substituents, such as 3-methyl-3-(meth)acryloxymethyloxetane, 3-ethyl-3-(meth)acryloxymethyloxetane, 3-methyl-3-(meth)acryloxyethyloxetane, etc.; unsaturated glycidyl carboxylic acid ester compounds, such as glycidyl(meth)acrylate, etc.; unsaturated carboxylic acid ester compounds having aromatic ring-containing substituents, such as benzyl(meth)acrylate, phenoxy(meth)acrylate, etc.; aromatic vinyl compounds, such as styrene, vinyl toluene, α-methyl styrene, etc.; carboxylic acid vinylesters, such as vinyl acetate, vinyl propionate, etc.; cyanated vinyl compounds, such as (meth)acrylonitrile, α-chloroacrylonitrile, etc., which can be used alone or in combination with two or more thereof.

Examples of the copolymer may include 3-ethyl-3-methacryloxymethyloxetane/benzyl methacrylate/methacrylic acid copolymer, 3-ethyl-3-methacryloxymethyloxetane/benzyl methacrylate/methacrylic acid/styrene copolymer, 3-ethyl-3-methacryloxymethyloxetane/methyl methacrylate/methacrylic acid copolymer, 3-ethyl-3-methacryloxymethyloxetane/methyl methacrylate/methacrylic acid/styrene copolymer, or the like.

The polymerizable compound is without limitation and may be any compound generally used in the related art, for example, a compound having an epoxy group hardened by heat.

The compound having an epoxy group is without limitation and may include, for example, a curable monomer having an epoxy(meth)acrylate group.

The curable monomer having an epoxy(meth)acrylate group may be any one selected from commercially available compounds, for example, a compound having two epoxy acrylate groups or four epoxy acrylate groups in the molecule.

The polymerization initiator used herein is without limitation and may include any one used in the related art, for example, triazine compounds, acetophenone compounds, xanthone compounds, benzoin compounds, imidazole compounds, etc., which can be used alone or in combination with two or more thereof.

Particular examples of the polymerization initiator may include 2,4-bistrichloromethyl-6-p-methoxystyryl-s-triazine, 2-p-methoxystyryl-4,6-bistrichloromethyl-s-triazine, 2,4-trichloromethyl-6-triazine, 2,4-trichloromethyl-4-methylnaphthyl-6-triazine, benzophenone, p-(diethylamino)benzophenone, 2,2-dichloro-4-phenoxyacetophenone, 2,2-diethoxyacetophenone, 2,2-dibutoxyacetophenone, 2-hydroxy-2-methylpropiophenone, p-t-butyl 2,2,2-trichloroacetophenone, 2-methylthioxanthone, 2-isobutylthioxanthone, 2-dodecylthioxanthone, 2,4-dimethylthioxanthone, 2,4-diethylthioxanthone, 2,2′-bis-(2-chlorophenyl)-4,4′,5,5′-tetraphenyl-1,2-biimidazole compounds, etc., which can be used alone or in combination with two or more thereof.

The kinds of solvents used herein are without limitation and may include, for example, ethyleneglycol monoalkylethers, such as ethyleneglycol monomethylether, ethyleneglycol monoethylether, ethyleneglycol monopropylether, ethyleneglycol monobutylether, etc.; diethyleneglycol dialkylethers, such as diethyleneglycol dimethylether, diethyleneglycol diethylether, diethyleneglycol dipropylether, diethyleneglycol dibutylether, etc.; alkyleneglycol alkylether acetates, such as propyleneglycol monomethylether acetate, propyleneglycol monoethylether acetate, propyleneglycol monopropylether acetate, etc.; alkyleneglycol alkylethers, such as propyleneglycol monomethylether, propyleneglycol monoethylether, propyleneglycol monopropylether, etc.; (alkoxy)alkylesters, such as ethyl acetate, ethyl lactate, methylcellosolve acetate, ethylcellosolve acetate, methoxybutyl acetate, methoxypentyl acetate, etc.; aromatic hydrocarbons, such as benzene, toluene, xylene, etc.; ketones, such as methylethylketone, acetone, methylamylketone, methylisobutylketone, cyclohexanone, etc.; alcohols, such as ethanol, propanol, butanol, hexanol, cyclohexanol, ethyleneglycol, glycerin, etc., which can be used alone or in combination with two or more thereof.

The thickness of a non-conductive shielding pattern may range from 1 to 10 μm, and preferably ranges from 1 to 5 μm. When the thickness of the non-conductive shielding pattern is within the range from 1 to 10 μm, hiding and shielding effects are attained to mask the inner board and wiring of the device, the reliability of the conductive electrode pattern layer may be improved, and a thin touch screen panel may be produced.

After forming the non-conductive shielding pattern, an electromagnetic wave shielding layer and an index matching layer may be further provided, as described above.

Thereafter, an electrode pattern, an insulating layer, or the like, may be further provided. The electrode pattern may play a role in detecting static electricity generated from the body of a human when his or her finger touches a display part as a touch area of an image sensor, and converting it to electric signals.

The conductive material used for forming the electrode pattern is without limitation and may include, for example, indium-tin oxide (ITO), indium-zinc oxide (IZO), zinc oxide (ZnO), indium-zinc-tin oxide (IZTO), cadmium-tin oxide (CTO), poly(3,4-ethylenedioxythiopene) (PEDOT), carbon nanotube (CNT), metal wire, etc., which can be used alone or in combination with two or more thereof.

Metals used in the metal wire are without limitation and may include, for example, silver, gold, aluminum, copper, iron, nickel, titanium, tellurium, chromium, etc., which can be used alone or in combination with two or more thereof.

According to the above, an electrode pattern circuit may be formed on an area corresponding to the non-display part in the electrode pattern. The electrode pattern circuit plays a role in delivering the electrical signal generated from the electrode pattern to a flexible printed circuit board (FPCB), IC chips, or the like, by touching the display part of the window substrate. The electrode pattern circuit may be formed of the same materials and by the same methods as used for forming the electrode pattern.

Thereafter, a scattering-preventive film may be provided. The scattering-preventive film may play a role in protecting the above patterns and preventing the same from being scattered when the window substrate is broken.

Materials for the scattering-preventive film are without limitation so long as they are transparent and provide durability, and may include, for example, polyethylene terephthalate (PET).

A method for forming the scattering-preventive film is without limitation and may include, for example, spin coating, roll coating, spray coating, dip coating, flow coating doctor blade and dispensing, inkjet printing, screen printing, pad printing, gravure printing, offset printing, flexography printing, stencil printing, imprinting, and the like.

Next, the electrode pattern circuit may be connected to a terminal of a printed circuit board. Various types of printed circuit boards may be used, for instance, a flexible printed circuit board (FPCB) may be used.

A touch screen panel prepared by the above processes, according to the present invention, includes an electromagnetic wave shielding layer that reduces harmful effects to the human body while decreasing the malfunction of peripheral electronic devices, as well as the touch screen panel.

What is claimed is:

1. A touch screen panel, comprising: an electromagnetic wave shielding layer on a window substrate.

2. The touch screen panel according to claim 1, wherein the electromagnetic wave shielding layer includes at least one alloy selected from the group consisting of copper, iron, nickel, aluminum, tin, indium, zinc, gold and silver, and oxides thereof, as an electromagnetic wave shielding material.

3. The touch screen panel according to claim 1, wherein the electromagnetic wave shielding layer includes at least one electromagnetic wave shielding material selected from the group consisting of polypyrrole, polythiophene, and polyaniline.

4. The touch screen panel according to claim 1, further comprising an index matching layer, the electromagnetic wave shielding layer formed on at least one face of the index matching layer.

5. The touch screen panel according to claim 4, wherein the index matching layer includes niobium oxide or silicon oxide, or a mixture thereof.

6. The touch screen panel according to claim 1, wherein the electromagnetic wave shielding layer is formed directly on at least one face of a window substrate.

7. The touch screen panel according to claim 1, further comprising an insulating layer, the electromagnetic wave shielding layer formed on at least one face of the insulating layer.

8. The touch screen panel according to claim 4, wherein the electromagnetic wave shielding layer is formed from a composition comprising an electromagnetic wave shielding material, binder resin and solvent.

9. The touch screen panel according to claim 1, wherein the electromagnetic wave shielding layer is an index matching layer.

10. The touch screen panel according to claim 9, wherein the index matching layer includes an electromagnetic wave shielding material.

11. The touch screen panel according to claim 9, wherein the index matching layer is prepared by combining niobium oxide or silicon oxide with electromagnetic wave shielding material.
